(19) United States
(12) Patent Application Publication
(10) Pub. No.: US 2016/0225445 A1
(43) Pub. Date: Aug. 4, 2016

(54) WRITING METHOD AND READING METHOD OF PHASE CHANGE MEMORY

(71) Applicant: MACRONIX INTERNATIONAL CO., LTD., Hsinchu (TW)

(72) Inventors: Chao-I Wu, Hsinchu City (TW); Ming-Hsiu Lee, Hsinchu City (TW)

(21) Appl. No.: 14/609,595

(22) Filed: Jan. 30, 2015

(51) Int. Cl. G11C 13/00

(52) U.S. Cl. CPC G11C 13/0069; G11C 13/0004; G11C 13/004

(57) ABSTRACT

A writing method and a reading method of a phase change memory (PCM) are provided. The PCM has a plurality of memory cells. The writing method comprises the following steps. At least one stress pulse is applied for aging at least one of the memory cells. A starting pulse is applied to all of the memory cells of the PCM for increasing a resistance of each of the memory cells. A detection pulse is applied to all of the memory cells of the PCM for decreasing the resistance of each of the memory cells and detecting the resistance changing speed of each of the memory cells. A set pulse is applied to the aged memory cells. A reset pulse is applied to the non-aged memory cells.

### BACKGROUND

1. Technical Field

The disclosure relates in general to a writing method and a reading method of a memory, and more particularly to a writing method and a reading method of a phase change memory.

2. Description of the Related Art

With the development of technology, varied memories are invented. For example, flash memories, magnetic core memories or phase change memories (PCM) are used in electronic devices.

Phase change memory is a type of non-volatile random-access memory. The material of the PCM maybe, Ge₂Sb₂Te₅ (GST), or GeTe—Sb₂Te₃. The material of the PCM can be switched between a crystalline state and an amorphous state for storing digital data.

### SUMMARY

The disclosure is directed to a writing method and a reading method of a phase change memory.

According to an embodiment of the present disclosure, a writing method of a phase change memory (PCM) is provided. The PCM has a plurality of memory cells. The writing method comprises the following steps. At least one stress pulse is applied for aging at least one of the memory cells. A starting pulse is applied to all of the memory cells of the PCM for increasing a resistance of each of the memory cells. A detection pulse is applied to all of the memory cells of the PCM for decreasing the resistance of each of the memory cells and detecting a resistance changing speed of each of the memory cells, wherein the resistance changing speeds of aged memory cells are higher than the resistance changing speeds of the non-aged memory cells. A set pulse is applied to the aged memory cells. The reset pulse is applied to the non-aged memory cells.

According to another embodiment of the present disclosure, a reading method of a phase change memory (PCM) is provided. The PCM has a plurality of memory cells. The reading method comprises the following steps. A starting pulse is applied to all of the memory cells of the PCM for increasing a resistance of each of the memory cells. A detection pulse is applied to all of the memory cells of the PCM for decreasing the resistance of each of the memory cells and detecting the resistance of each of the memory cells. If the resistance of one of the memory cells is lower than a predetermined value, then the memory cell whose resistance is decreased to be lower than the predetermined value is determined to be at a low resistance state. If the resistance of one of the memory cells is decreased to be equal to or higher than the predetermined value, then the memory cell whose resistance is not lower than the predetermined value is determined to be at a high resistance state.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a flowchart of a writing method of a phase change memory (PCM);

FIG. 2 shows a resistance curve of a non-aged memory cell and a resistance curve of an aged memory cell before a high temperature process;

FIG. 3 shows a resistance curve of a non-aged memory cell and a resistance curve of an aged memory cell after a high temperature process;

FIG. 4A shows resistance curves of memory cells before and after a high temperature process according to a comparative embodiment of the present disclosure;

FIG. 4B shows a resistance curve of an aged memory cell after a high temperature process according to an embodiment of the present disclosure; and

FIG. 4C shows a resistance curve of a non-aged memory cell after a high temperature process according to an embodiment of the present disclosure.

### DETAILED DESCRIPTION

Embodiments are disclosed below for elaborating the invention. The following embodiments are for the purpose of elaboration only, not for limiting the scope of protection of the invention. Besides, secondary elements are omitted in the following embodiments to highlight the technical features of the invention.

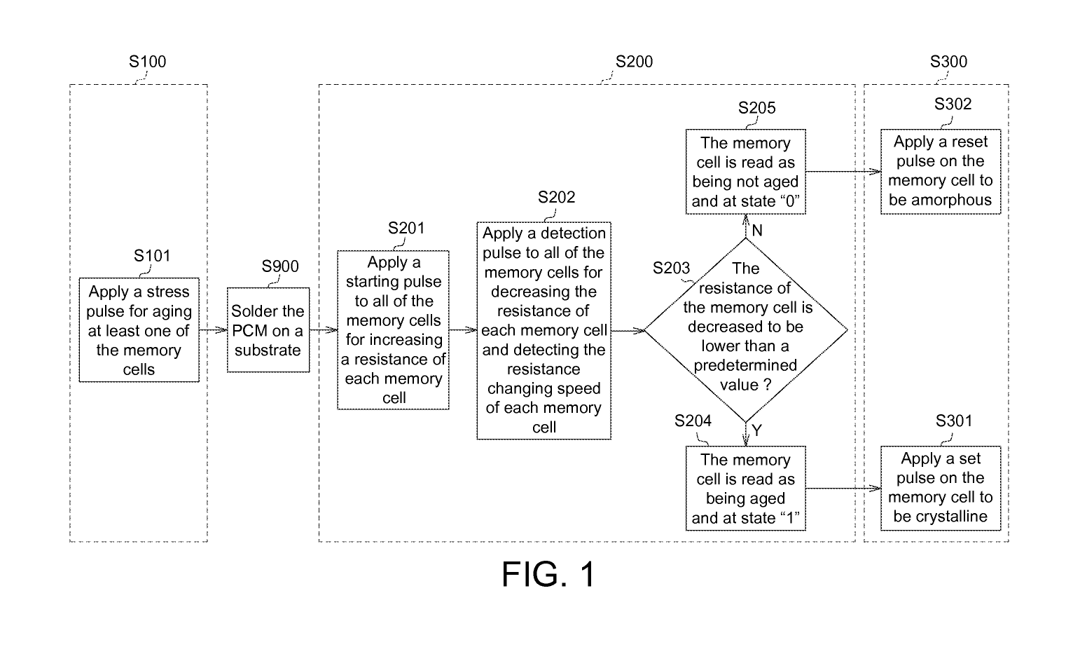

FIG. 1 shows a flowchart of a writing method of a phase change memory (PCM). The writing method of the PCM includes a pre-coded data writing procedure S100, a pre-coded data reading procedure S200 and a user data writing procedure S300. The pre-coded data writing procedure S100 is used for writing a pre-coded data into the PCM. The pre-coded data can be remained under an environment which is higher than 300° C. and will not be lost during any high temperature process, such as a soldering process. The pre-coded data reading procedure S200 is used for reading the pre-coded data of the PCM after the high temperature process. The user data writing procedure S300 is used for writing a user data into the PCM after the high temperature process. Because the user data is written after the high temperature process, the user data will not be lost.

The PCM has a plurality of memory cells. For example, each of the memory cells can be written “0” or “1.” In step S101, at least one stress pulse is applied for aging at least one of the memory cells. The at least one of the memory cells which is aged is written as being at state “1.” The others of the memory cells which are not aged are defined as being at state “0.”

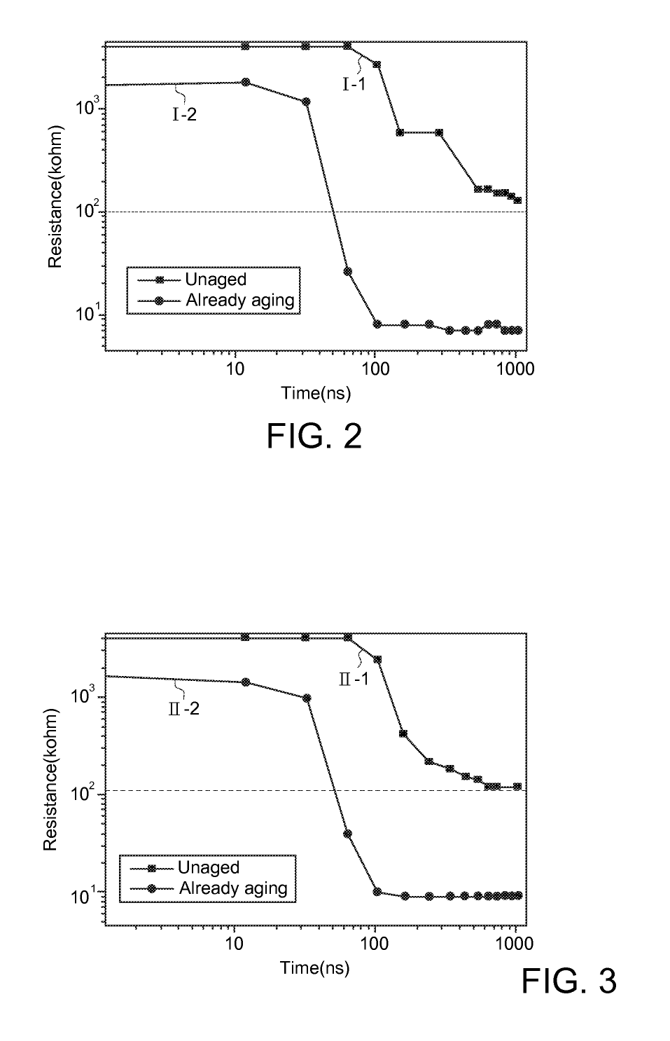

FIG. 2 shows a resistance curve I-1 of a non-aged memory cell and a resistance curve I-2 of an aged memory cell before a high temperature process. Comparing the non-aged memory cell and the aged memory cell, the resistance curve I-1 is different from the resistance curve I-2. After the stress pulse is applied, the memory cell is aged and the resistance curve I-1 is shifted toward left and becomes the resistance curve I-2 and the SET speed is increased. That is to say, the time required for setting the memory cell from being at a high resistance state to be at a low resistance state is reduced. Taking FIG. 2 as an example, while a set pulse is applied for 100 ns, the resistance of the non-aged memory cell is about higher than 10³ Kohm, and the resistance of the aged memory cell is about less than 1 Kohm. The difference between the resistance curve I-1 of the non-aged memory cell and the resistance curve I-2 of the aged memory cell is called an aging effect or a stress effect.

According to the embodiments of the present disclosure, the total energy of the stress pulse applied on the memory cell is used for aging the memory cell. In the embodiment, applying the stress pulse may include many methods, such as DC current stress, cycling, SET waveform cycling, RESET waveform cycling, combined RESET/SET waveform cycling, and etc. In one embodiment, the current of the stress pulse can be fixed. In one embodiment, the current of the stress pulse can be decreased. In one embodiment, the current of the stress pulse can be applied as a plurality of pulses.

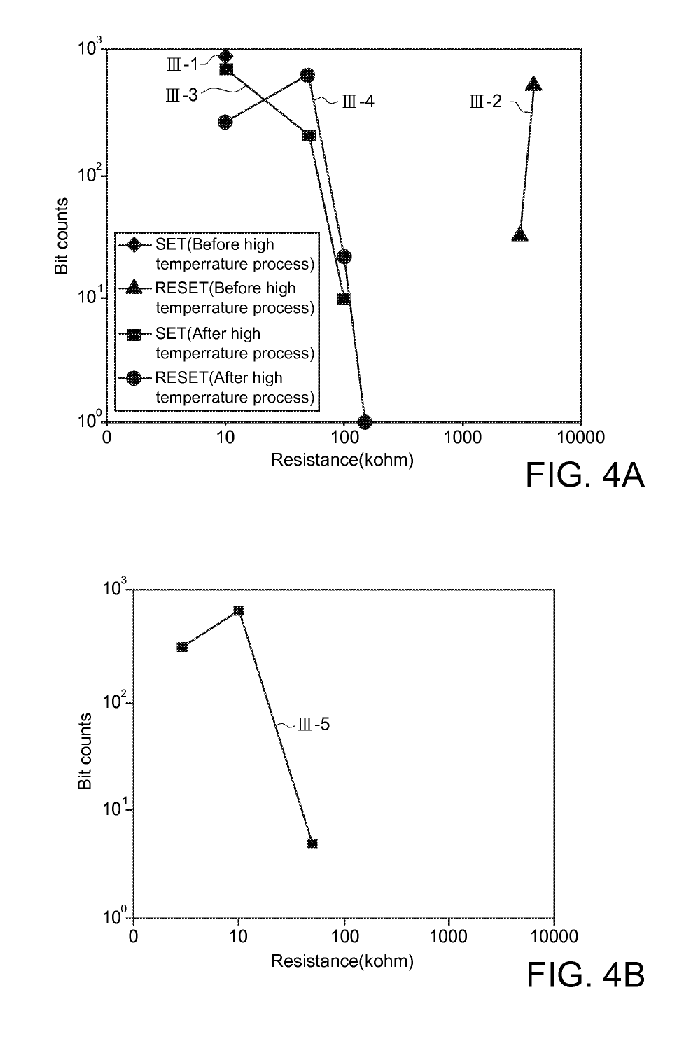

Referring to FIG. 1, in step S900, the PCM is soldered on a substrate. During the step S900 of soldering, the temperature might be higher than 260° C. Please referring to FIG. 3, FIG. 3 shows a resistance curve II-1 of a non-aged memory cell and a resistance curve II-2 of an aged memory cell after a high temperature process. Comparing the non-aged memory cell and the aged memory cell, the resistance curve II-1 is different from the resistance curve II-2. The difference between the resistance curve II-1 of the non-aged memory cell and the resistance curve II-2 of the aged memory cell is existed. That is to say, the aging effect (or called the stress effect) is still existed after the high temperature process. Therefore, the pre-coded data written by applying the stress pulse will not be lost during the high temperature process.

Please referring to FIG. 1, in step S201, a starting pulse is applied to all of the memory cells of the PCM for increasing a resistance of each of the memory cells. For example, the current of the starting pulse may be 50-400 μA and the resistance of each of the memory cells is increased to being higher than a predetermined value, such as 100 Kohm to 1 Mohm.

In step S202, a detection pulse is applied to all of the memory cells of the PCM for decreasing the resistance of each of the memory cells and detecting the resistance changing speed of each of the memory cells. The current of the detection pulse is lower than that of the starting pulse. In an embodiment, the current of the detection pulse is such as ½−¼ of that of the starting pulse. Please refer to FIG. 3, for example, the current of the detection pulse may be 20-250 μA applied for 10-1000 ns, such as 100 μA, and then there is a big difference between the resistance of the non-aged memory cell and the resistance of the aged memory as the detection pulse is applied. In other words, there is a big difference between the resistance changing speed of the non-aged memory cell and the resistance changing speed of the aged memory. In this step, the detection pulse may be an 80 microampere (μA) current applied for 100 ns.

In the embodiment, at the same time point in the duration of applying the detection pulse, for example while the detection pulse is applied for 100 ns, the detected difference between the resistance of the non-aged memory cell and the resistance of the aged memory cell represents the difference between the resistance changing speeds of the non-aged memory cell and the aged memory cell. According to the embodiments of the present disclosure, the resistance changing speeds of the aged memory cells are higher than the resistance changing speeds of the non-aged memory cells. For example, memory cells would have substantially the same high resistance after applied with the starting pulse; as such, after the detection pulse is subsequently applied to the memory cells for the same time period, the memory cells detected with lower resistance indicate that these memory cells have a larger resistance change per unit time, e.g. the resistance is decreased by a larger amount, representing the memory cells having higher resistance changing speeds.

In step S203, whether the resistance of the memory cell is decreased to be lower than the predetermined value, such as 100 Kohm, is determined. If the resistance is decreased to be lower than the predetermined value, then the memory cell is determined to be at a low resistance and having a higher resistance changing speed, and the process proceeds to step S204; if the resistance is decreased to be not lower than the predetermined value, that is, the resistance is equal to or higher than the predetermined value, then the memory cell is determined to be at a high resistance and having a lower resistance changing speed, and the process proceeds to step S205.

In step S204, the memory cell whose resistance is lower than the predetermined value and having a higher resistance changing speed is read as being aged and at state “1.”

In step S205, the memory cell whose resistance is equal to or higher than the predetermined value and having a lower resistance changing speed is read as being not aged and at state “0.”

Base on above, by performing the steps S201 to S205, the pre-coded data can be read without being lost after any high temperature process.

Afterwards, in step S301, a set pulse is applied on the memory cell which is read as being aged and at state “1” to be crystalline. When the set pulse is applied on the memory cell, the molecule of the memory is melted. Then, the memory cell is quenched to arrange the molecule. In this step, the current of the set pulse is low and the set pulse is applied for a long time for well arrange the molecule to be crystalline.

In step S302, a reset pulse is applied on the memory cell which is read as being not aged and at state “0” to be amorphous. When the reset pulse is applied on the memory cell, the molecule of the memory is melted. Then, the memory cell is quenched to arrange the molecule. In this step, the current of the reset pulse is high and the reset pulse is applied for a short time for badly arrange the molecule to be amorphous.

Regarding the detection pulse in the step S202, the detection pulse is different from the reset pulse and is different from the set pulse. The detection pulse is not used for making all of the memory cells to be crystalline, and is not used for making all of the memory cells to be amorphous. Actually, the detection pulse will make the non-aged memory cells to be amorphous, and make the aged memory cells to be crystalline.

Regarding the starting pulse in the step S201, the starting pulse may be identical to the reset pulse of the step S302. The starting pulse in the step S201 is used for making all of the memory cells to be amorphous. Therefore, the molecules of the memory cells can be rearranged to be crystalline or amorphous in the next step S202.

In other embodiment, the starting pulse may be different from the reset pulse of the step S302. The starting pulse can be designed as any form, as long as the molecules of all of the memory cells can be formed to be amorphous.

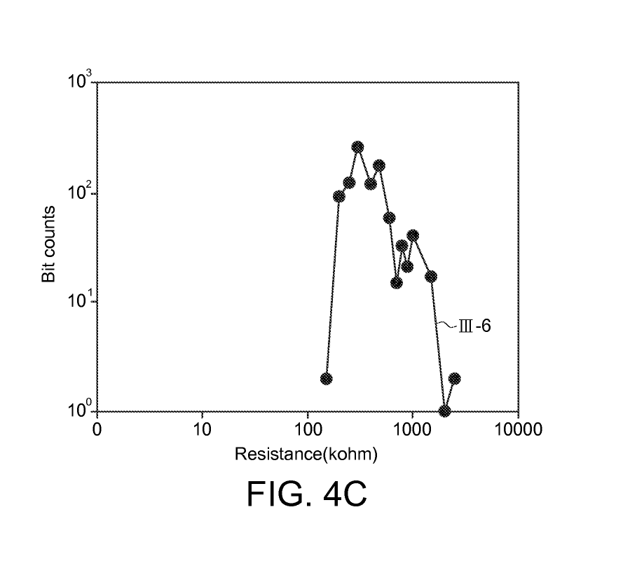

FIG. 4A shows resistance curves of memory cells before and after a high temperature process according to a comparative embodiment. While a memory cell is read according to a conventional method, before a high temperature process is performed to the memory cell, the memory cell being crystalline and having a low resistance after applied with a set pulse has a resistance curve III-1, and the memory cell being amorphous and having a high resistance after applied with a reset pulse has a resistance curve III-2. As shown in FIG. 4A, there two resistance curves III-1 and III-2 are highly different from each other.

However, after a high temperature process, the high-temperature heat treatment influences the crystallinity of the materials of the memory cells of the PCM. Therefore, the crystalline of the memory cell, which has a low resistance and the resistance curve III-1, is destructed by the heat treatment after the high temperature process, and the resistance curve III-1 is changed to the resistance curve III-3. Likewise, the crystalline of the memory cell, which has a high resistance and the resistance curve III-2, is influenced by the heat treatment after the high temperature process, and the resistance curve III-2 is changed to the resistance curve III-4. As shown in FIG. 4A, as the crystallinity of the memory cells are influenced by the high temperature process, the resistance difference between the two resistance curves III-3 and III-4 becomes too small to be distinguished. In other words, if the states “0” and “1” are defined by the crystallinity according to the conventional method, then these states may be destructed after a high temperature process, and the data of the PCM may be lost.

FIG. 4B shows a resistance curve of an aged memory cell after a high temperature process according to an embodiment, and FIG. 4C shows a resistance curve of a non-aged memory cell after a high temperature process according to an embodiment. According to the embodiments of the present disclosure, the memory cells applied with the stress pulse are aged and written as being at state “1”, and the other of the memory cells which are not aged are defined as being at state “0”. For example, the memory cell having the resistance curve III-3 as shown in FIG. 4A is aged, and the memory cell having the resistance curve III-4 is not aged.

As shown in FIG. 4B, after applying the starting pulse to all of the memory cells of the PCM for increasing the resistance of each of the memory cells and after applying the detection pulse to all of the memory cells of the PCM for decreasing the resistance of each of the memory cells, the resistance curve III-3 of an aged memory cell is shifted and becomes the resistance curve III-5. Likewise, as shown in FIG. 4C, after applying the starting pulse to all of the memory cells of the PCM for increasing the resistance of each of the memory cells and after applying the detection pulse to all of the memory cells of the PCM for decreasing the resistance of each of the memory cells, the resistance curve III-4 of a non-aged memory cell is shifted and becomes the resistance curve III-6.

In the embodiment, after the detection pulse is applied to an aged memory cell and to a non-aged memory cell, there is a big difference between the speeds of the resistance decrease of the aged memory cell and the non-aged memory. Accordingly, as shown in FIGS. 4B-4C, after a high temperature process, there is a big difference between the resistance of the resistance curve III-5 and the resistance of the resistance curve III-6, which resistance are detected after the detection pulse is applied for a certain period of time, and hence the different states of the memory cell having the resistance curve III-5 and the memory cell having the resistance curve III-6 can be easily distinguished from each other. In other words, according to the embodiments of the present disclosure, the states “0” and “1” of the memory cells are not defined by the crystallinity by a conventional way; on the contrary, the states of the memory cells are defined by the aging process, which determines the states of predetermined memory cells. Therefore, these states are not destroyed by the heat treatment after a high temperature process, and the data stored in the PCM can be well preserved.

Base on above, the PCM comprises the pre-coded data and the user data. The pre-coded data is written by applying at least one stress pulse for aging at least one of the memory cells. The at least one of the memory cells which is aged is at state “1.” The others of the memory cells which are not aged are at state “0.”

The user data is written by applying a set pulse or a reset pulse on at least one of the memory cells to be crystalline or amorphous. For example, the memory cells which are amorphous are at state “1”, and the memory cells which are crystalline are at state “0.” The user data and the pre-coded data are independent and can be written or read respectively.

In one embodiment, the pre-coded data may be identical to the user data. In other embodiment, the pre-coded data may be different from the user data.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A writing method of a phase change memory (PCM), wherein the PCM has a plurality of memory cells, and the writing method comprises:
applying at least one stress pulse for aging at least one of the memory cells, wherein the memory cells comprise aged memory cells and non-aged memory cells after applying the least one stress pulse, the aged memory cells are at state “1”, and the non-aged memory cells are at state “0”;
applying a starting pulse to all of the memory cells of the PCM for increasing a resistance of each of the memory cells;
after applying the starting pulse to all of the memory cells, applying a detection pulse to all of the memory cells of the PCM for decreasing the resistance of each of the memory cells and detecting a resistance changing speed of each of the memory cells, wherein the resistance changing speeds of the aged memory cells are higher than the resistance changing speeds of the non-aged memory cells;
applying a set pulse to the aged memory cells; and
applying a reset pulse to the non-aged memory cells;
wherein a current of the detection pulse is lower than a current of the starting pulse.

2. The writing method of the PCM according to claim 1, further comprising:
soldering the PCM on a substrate, wherein the step of applying the at least one stress pulse is performed before the step of soldering the PCM.

3. The writing method of the PCM according to claim 1, further comprising:
if the resistance of one of the memory cells is decreased to be lower than a predetermined value, then the memory cell whose resistance is lower than the predetermined value is read as being aged; and
if the resistance of one of the memory cells is decreased to be equal to or higher than the predetermined value, then the memory cell whose resistance is equal to or higher than the predetermined value is read as being not aged.

4. The writing method of the PCM according to claim 3, wherein the predetermined value is 100 Kohm.

5. The writing method of the PCM according to claim 1, wherein the step of applying the set pulse and the step of applying the reset pulse are performed after the step of soldering the PCM.

6. The writing method of the PCM according to claim 1, wherein the detection pulse is a 20-250 microampere (μA) current applied for 10-1000 ns.

7. The writing method of the PCM according to claim 1, wherein a current of the detection pulse is an 80 μA current applied for 100 ns.

8. (canceled)

9. The writing method of the PCM according to claim 1, wherein a current of the starting pulse is 50 to 400 μA.

10. The writing method of the PCM according to claim 1, wherein the starting pulse is identical to the reset pulse.

11. The writing method of the PCM according to claim 1, wherein the starting pulse is different from the reset pulse.

12. A reading method of a phase change memory (PCM), wherein the PCM has a plurality of memory cells, the reading method comprises:
applying a starting pulse to all of the memory cells of the PCM for increasing a resistance of each of the memory cells;
after applying the starting pulse to all of the memory cells, applying a detection pulse to all of the memory cells of the PCM for decreasing the resistance of each of the memory cells and detecting the resistance of each of the memory cells, wherein a current of the detection pulse is lower than a current of the starting pulse;
if the resistance of one of the memory cells is decreased to be lower than a predetermined value, then the memory cell whose resistance is lower than the predetermined value is read as being at a low resistance state; and
if the resistance of one of the memory cells is decreased to be equal to or higher than the predetermined value, then the memory cell whose resistance is decreased to be equal to or higher than the predetermined value is read as being at a high resistance state.

13. The reading method of the PCM according to claim 12, wherein the detection pulse is a 25-200 microampere (μA) current applied for 10-1000 ns.

14. The reading method of the PCM according to claim 12, wherein the detection pulse is an 80 μA current applied for 100 ns.

15. (canceled)

16. The reading method of the PCM according to claim 12, wherein a current of the starting pulse is 50 to 400 μA.

17. The reading method of the PCM according to claim 12, wherein the predetermined value is 100 Kohm to 1 Mohm.
